(19) United States
(12) Patent Application Publication
(10) Pub. No.: US 2020/0388723 A1
(43) Pub. Date: Dec. 10, 2020

(54) MICRO LIGHT-EMITTING DIODE DISPLAY HAVING TRUNCATED NANOPYRAMID STRUCTURES

(71) Applicant: Intel Corporation, Santa Clara, CA (US)

(72) Inventors: Khaled AHMED, Anaheim, CA (US); Sansaptak DASGUPTA, Hillsboro, OR (US)

(21) Appl. No.: 16/435,312

(22) Filed: Jun. 7, 2019

(51) Int. Cl. H01L 33/24; H01L 25/075; H01L 27/12; H01L 29/786; H01L 33/06; H01L 33/08; H01L 33/32; H01L 33/42; H01L 33/44; H01L 33/60; H01L 33/62

(52) U.S. Cl. CPC H01L 33/24; H01L 25/0753; H01L 27/1225; H01L 27/1222; H01L 29/78678; H01L 29/7869; H01L 33/62; H01L 33/08; H01L 33/32; H01L 33/42; H01L 33/44; H01L 33/60; H01L 33/06

(57) ABSTRACT

Micro light-emitting diode structures, displays, display fabrication processes, and assembly apparatuses are described. In an example, light-emitting diode structure includes a GaN truncated nanopyramid above a substrate, and an InGaN active layer over the GaN truncated nanopyramid.

### TECHNICAL FIELD

Embodiments of the disclosure are in the field of micro-LED displays and, in particular, micro light-emitting diode structures, displays, display fabrication processes, and assembly apparatuses.

### BACKGROUND

Displays having micro-scale light-emitting diodes (LEDs) are known as micro-LED, mLED, and μLED. As the name implies, micro-LED displays have arrays of micro-LEDs forming the individual pixel elements.

A pixel may be a minute area of illumination on a display screen, one of many from which an image is composed. In other words, pixels may be small discrete elements that together constitute an image as on a display. These primarily square or rectangular-shaped units may be the smallest item of information in an image. Pixels are normally arranged in a two-dimensional (2D) matrix, and are represented using dots, squares, rectangles, or other shapes. Pixels may be the basic building blocks of a display or digital image and with geometric coordinates.

### BRIEF DESCRIPTION OF THE DRAWINGS

FIGS. 1A and 1B illustrate cross-sectional views of operations in an epitaxial growth process for fabricating truncated nanopyramids for micro LED devices, in accordance with an embodiment of the present disclosure.

FIGS. 2A and 2B illustrate cross-sectional views of operations in a comparative epitaxial growth process for fabricating nanopyramids for micro LED devices.

FIG. 3 includes plots depicting an exemplary process for forming a plurality of truncated nanopyramids using a two-stage growth mode, in accordance with an embodiment of the present disclosure.

FIG. 4 illustrates a schematic of micro LED display architecture, in accordance with an embodiment of the present disclosure.

FIG. 5A illustrates a cross-sectional view of a truncated nanopyramid based LED highlighting certain layers of the LED, in accordance with an embodiment of the present disclosure.

FIG. 5B illustrates a cross-sectional view of a nanowire based LED highlighting certain layers of the LED, in accordance with an embodiment of the present disclosure.

FIG. 5C illustrates a cross-sectional view of a nanopyramid or micropyramid based LED highlighting certain layers of the LED, in accordance with an embodiment of the present disclosure.

FIG. 5D illustrates a cross-sectional view of an axial nanowire based LED highlighting certain layers of the LED, in accordance with an embodiment of the present disclosure.

FIG. 6 illustrates a cross-sectional view of an RGB chip with three truncated nanopyramid based LEDs, in accordance with an embodiment of the present disclosure.

FIG. 7A illustrates a cross-sectional view of assembly components (e.g., micro LED wafer and display backplane) during “selective bonding” of micro LEDs, in accordance with an embodiment of the present disclosure.

FIG. 7B illustrates a cross-sectional view of assembly components (e.g., micro LED wafer and display backplane) during “selective release” of micro LEDs, in accordance with an embodiment of the present disclosure.

FIGS. 8A-8E illustrate cross-sectional views of various operations in a method of assembling a micro LED display, in accordance with an embodiment of the present disclosure.

FIG. 9 is a schematic illustration of a micro light emitting diode (LED) display architecture, in accordance with an embodiment of the present disclosure.

FIG. 10 illustrates a cross-sectional view of a schematic of a display bonder apparatus, in accordance with an embodiment of the present disclosure.

FIG. 11A illustrates a cross-sectional view of a display backplane prior to having micro LEDs bonded thereon, in accordance with an embodiment of the present disclosure.

FIG. 11B illustrates a cross-sectional view of a display backplane having a micro LED bonded thereon, in accordance with an embodiment of the present disclosure.

FIG. 12 is a flow diagram illustrating a red green blue (RGB) display production process, in accordance with an embodiment of the present disclosure.

FIG. 13 is an electronic device having a display, in accordance with embodiments of the present disclosure.

### DESCRIPTION OF THE EMBODIMENTS

Micro light-emitting diode (LED) displays having truncated nanopyramid structures are described. In the following description, numerous specific details are set forth, such as specific material and structural regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

One or more embodiments described herein are directed to truncated nanopyramid light emitting diode (LED)s for facile production of high color purity and low power micro LED displays. It is to be appreciated that monolithic manufacturing of high efficiency green and blue μLEDs has been demonstrated using nanowire LED technology based on a gallium nitride (GaN) material system. However, it has proven challenging to obtain high efficiency red using the GaN material system. Embodiments of the present disclosure may be directed to a device and method for fabricating full-color micro light emitting diode (μLED) displays.

To provide context, displays based on inorganic micro LEDs (μLEDs) have attracted increasing attention for applications in emerging portable electronics and wearable computers such as head-mounted displays and wristwatches. Micro LEDs are typically first manufactured on Sapphire or silicon wafers (for example) and then transferred onto a display backplane glass substrate where on which active matrix thin-film transistors have been manufactured. The target acceptable defect density after such a transfer is approximately 1-2 ppm. This low defect density requirement may be achieved by transferring two micro LEDs for each color (red, green and blue), a so-called “redundancy strategy.” However, transferring more micro LEDs for redundancy may result in higher manufacturing cost.

One or more embodiments described herein are directed to devices and methods for micro LED assembly. In an embodiment, a device and method for fabricating full-color micro light emitting diode (μLED) displays by micro transfer assembly. Micro LED displays promise 3×-5× less power compared to organic LED (OLED) displays. The difference would result in a savings in battery life in mobile devices (e.g., notebook and converged mobility) and can enhance user experience. In an embodiment, micro LED displays described herein consume two-fold less power compared to organic LED (OLED) displays. Such a reduction in power consumption may provide an additional approximately 8 hours of battery life. Such a platform may even outperform platforms based on low power consumption central processing units (CPUs). Embodiments described herein may be associated with one or more advantages such as, but not limited to, high manufacturing yield, high manufacturing throughput (display per hour), and applicability for displays with a diagonal dimension ranging from 2 inches to 15.6 inches.

To date, options for fabricating efficient red micro LEDs have included planar structures, core-shell nanowire structures, axial nanowire structures, or nanopyramid structures. However, a planar structure does not allow for the formation of InGaN active layers with indium content higher than 32% (of total indium plus gallium content) and, thus, efficient red emission is not possible. Core-shell nanowires have relatively lower indium incorporation on the m-plane, making it difficult to reach greater than 40% indium composition (of total indium plus gallium content) required for red emission. Axial nanowires allow for high indium incorporation and relatively higher efficiency for red micro LEDs, however, molecular beam epitaxy (MBE) is typically required for the growth. MBE has proven to not be scalable to 300 mm size wafers, which negatively affects the economics of fabricating micro LED displays. Finally, the nanopyramid structure can allow for high indium incorporation on the r-planes. However, the indium composition along the pyramid facets is non-uniform, leading to a 2× wider emission spectrum, negatively affecting the color purity and color gamut of the display.

Addressing the above issues, in accordance with an embodiment of the present disclosure, a truncated pyramid (nanopyramid) structure is implemented to achieve high efficiency red micro LEDs with narrow (e.g., less than 60 nm) Full-Width-Half-Maximum (FWHM) emission spectral width at a center wavelength of approximately 630 nm. A truncated nanopyramid structure may provide for facile manufacturing of micro LEDs on 300 mm silicon wafers, enabling affordable micro LED displays that have high color purity and low power consumption.

To provide further context, for light emitting devices, such as light emitting diodes (LED), the emission wavelength is determined by the band gap of the active region of the LED together with thickness determined confinement effects. Often, the active region includes one or more quantum wells (QWs). For Group III-nitride based LED devices, such as GaN based devices, the active region (e.g., quantum well) material is preferably ternary, such as InxGai-xN, where OX1. The band gap of such Group III-nitrides is dependent on the amount of indium (In) incorporated in the active region (e.g., in the QW(s)). Higher In incorporation will yield a smaller band gap and thus longer wavelength of the emitted light. InGaN is a very attractive material for the development of various optical devices in the entire visible spectral range owing to the tenability of the bandgap energy by adjusting the indium content. A low-In-content InGaN-based blue light-emitting diode (LED) has exhibited an internal quantum efficiency (IQE) of approximately 83%. However, the IQEs of long-wavelength LEDs emitting light in the green, yellow, orange, and red regions are much lower.

Factors leading to low efficiency in high-In-content InGaN-based LEDs may include one or more of: (1) defects in the InGaN active layer due to the lattice mismatch between InxGai-xN and GaN (e.g., lattice mismatch between InN and GaN is 11%), and/or (2) the piezoelectric field in the strained InGaN active layers can become very large for high indium content. The piezoelectric field can cause low internal quantum efficiency owing to electron—hole separation in InGaN multiple quantum wells. This may be particularly important for growing InGaN on c-plane GaN. For a/m-planes, the effect may be negligible.

It is to be appreciated that, beyond blue, long (green and red) visible light emitting diodes (LEDs) are required to make full-color micro LED displays. However, the efficiency of LEDs based on group III-nitrides radically decreases in long wavelengths (green and red) as attributed to the enlarged internal electric field and poor crystal quality with high Indium content in InGaN quantum wells (QWs). Three-dimensional nanostructures are promising candidates to overcome such problems. Generally, three-dimensional structures can increase light extraction efficiency, enlarge the emitting surface area, and relax the strain. Various approaches have been suggested to form three-dimensional nanostructures such as nanowires and nanopyramids. Vertically long nanowires can be obtained by catalysis-driven, self-organized, patterned growth. The nanopyramids can be formed mostly by selective area growth methods on patterned substrates. The pyramid structures are most attractive three-dimensional structures since the hexagonal pyramids are naturally grown by the low surface energy of the semipolar facets and, thus, highly crystalline, highly faceted structures, and semipolar facets can be readily obtained with have high Indium incorporation efficiency. InGaN QWs on nanopyramids show bright emission with reduced built-in electric fields in semipolar facets. The possibility of high Indium content with high crystal quality enables green and red luminescence from InGaN QWs on nanopyramids. However, the red color is still a challenging wavelength in InGaN QWs due to the limited In incorporation efficiency. Red emission can be observed only in a small portion (mostly the top region) of the nanostructures, molecular beam epitaxy (MBE)-grown vertical structures, or Indium-rich clusters (e.g., InGaN quantum dots) in an InGaN layer. Nanopyramids with InGaN/GaN double heterostructures have been implemented to eliminate the limitations of achieving high In-content InGaN and observe highly efficient red color emission from the high In-content InGaN layer. However, the emission spectrum of red light from such structures is about twice as wide as desired (i.e., the Full Width Half Maximum is 120 nm versus a target value of 60 nm). The wide spectral width was shown to stem from non-uniform indium composition along the side of the nanopyramid, with high indium composition (e.g., 45% of InGa portion) observed at the tip of the pyramids and low (e.g., 35% of InGa portion) observed at the base of the nanopyramid.

In accordance with one or more embodiments of the present disclosure, a non-lithographic process for fabricating Group III-nitride truncated nanopyramid LEDs by metal organic chemical vapor deposition (MOCVD) is described. The active region of such devices is located within a nanopyramid that grows atop a GaN “seed” nanorod. In one such embodiment, controlled seed nanorod synthesis is achieved by selective area epitaxy through a dielectric (e.g. Si3N4) template that also serves as a filter for the dislocations that thread through the underlying GaN film. In an embodiment, implementation of approaches described herein enables direct control of diameter and position of seed nanorods. In one embodiment, an additional benefit of this approach is that the hexagonal pyramid cap on each GaN seed nanorod includes six semipolar {1101} planes. InGaN quantum wells grown on {1101} semipolar planes may possess polarization-induced electric fields with magnitudes that are about a factor of ten lower than those in quantum wells of the same composition grown on c-plane GaN.

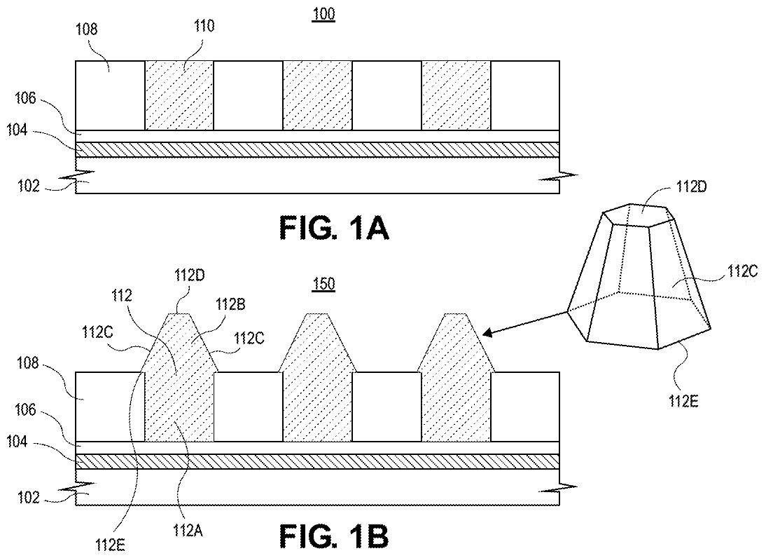

In an exemplary process scheme, FIGS. 1A and 1B illustrate cross-sectional views of operations in an epitaxial growth process for fabricating truncated nanopyramids for micro LED devices, in accordance with an embodiment of the present disclosure.

Referring to FIG. 1A, a starting structure 100 includes a substrate 102. Substrate 102 has a first nucleation layer 104 and a second nucleation layer 106 formed thereon. A dielectric mask 108 is formed to have openings therein exposing portions of the second nucleation layer 106. Nanorods 110 are formed in the openings in the dielectric mask 108 (such as a silicon nitride mask) in a first stage of an epitaxial growth process. In a particular embodiment, the substrate 102 is a 300 mm silicon (111) wafer, the first nucleation layer 104 is an aluminum nitride (A1N) layer having a thickness of about 25 nm, the second nucleation layer 106 is a niobium nitride (NbN) layer having a thickness of about 25 nm, and the nanorods 110 are N-type gallium nitride (such as silicon-doped gallium nitride or oxygen-doped gallium nitride). The openings in the dielectric mask 108 may have a diameter of about 50 nm. In an embodiment, the nanorods 110 are fabricated using continuous metal organic chemical vapor deposition (MOCVD) epitaxial growth.

Referring to FIG. 1B, truncated nanopyramid structures 112 are fabricated from the nanorods 110 following a second stage of the epitaxial growth process to form a structure 150. The truncated nanopyramid structures 112 each include a top truncated nanopyramid portion 112B and a nanorod portion 112A. In an embodiment, the top truncated nanopyramid portions 112B are fabricated using a pulsed-mode metal organic chemical vapor deposition (MOCVD) epitaxial growth. In an embodiment, the top truncated nanopyramid portions 112B are also N-type gallium nitride (such as silicon-doped gallium nitride or oxygen-doped gallium nitride), having the same or essentially the same composition as the nanorods 110. In an embodiment, any defects from the epitaxial growth process are confined to the nanorod portions 112A (originally 110) and do not propagate into the top truncated nanopyramid portions 112B. The top truncated nanopyramid portions 112B each include side facets 112C, a top facet 112D and, possibly, overhang portions 112E.

In an embodiment, following the second stage of the epitaxial deposition process of FIG. 1B, an active layer (e.g., InGaN) is formed on exposed surfaces of the top truncated nanopyramid portions 112B of the truncated nanopyramid structures 112. A cladding layer (e.g., P-type gallium nitride, such as magnesium-doped gallium nitride) is then formed on the active layer. In one embodiment, the active layer and the cladding layer are formed using pulsed epitaxial growth to control the indium composition uniformity in the InGaN active layer.

In an embodiment, selective area epitaxy of Group III-nitride nanopyramids is performed using an MOCVD reactor. In a particular exemplary embodiment, starting with a silicon (111) wafer, a thin layer (e.g., 25-50 nm) of AlN is grown epitaxally or using other methods. A thin layer (e.g., 25-50 nm) of a transition metal nitride (e.g. TiN, HfN, NbN, TaN, ZrN or the like) is deposited using sputtering deposition, for example. A silicon nitride layer (e.g., 300 nm) is deposited using atomic layer deposition (ALD) or plasma enhanced chemical vapor deposition (PECVD), and photolithography is used to pattern apertures in the silicon nitride with feature sizes of approximately 50 nm in diameter. The transition metal nitride can act as a nucleation layer for growing GaN nanorods. Epitaxial growth of GaN seed nanorods is then performed in the temperature range of 700°-1050° C. with trimethylgallium and ammonia (or hydrazine) as the Ga and N sources, respectively, e.g., using pulsed MOCVD epitaxial growth. As used herein, the term “pulsed growth mode” refers to a process in which the group III and group V precursor gases are introduced alternately in a crystal growth reactor with a designed sequence. For example, trimethyl gallium (TMGa) and NH3 (or Hydrazine N2H4) can be used as the precursors for an exemplary formation of GaN nanorods and InGaN active layers. In the pulsed growth mode, TMGa and NH3 (or Hydrazine N2H4) can be introduced alternately in a sequence that introduces TMGa with a designed flow rate (e.g., about 10 sccm) for a certain period of time (e.g., about 20 seconds) followed by introducing NH3 (or Hydrazine N2H4) with a designed flow rate (e.g., about 1500 sccm) for a time period (e.g., about 30 seconds). In various embodiments, one or more sequence loops can be conducted (e.g., repeated) for a designed length of each nanorod.

It is to be appreciated that the flows of the trimethylgallium and ammonia/hydrazine may be chosen for a low V/III molar ratio of less than 1500 so as to promote vertical growth. Using hydrogen as a carrier gas, the seed nanorod growth time may be about 5-10 minutes at a total pressure of approximately 100 torr. GaN seed nanorods may be Si-doped under growth conditions that may result in electron concentrations 1−10×10¹⁸ cm⁻³. The seed nanorods grown at relatively high temperature of 1030° C., for example, may terminate with a pyramidal cap primarily including six semipolar {1̅1̅01} facets (i.e., a “sharp” nanopyramid). Seed nanorods grown at relatively lower temperature of 980° C., for example, may possess a basal facet at the apex of their cap (a “truncated” nanopyramid). A truncated nanopyramid can result in a uniform indium composition along the facets of the nanopyramids (i.e., from base to tip) in the InGaN quantum well layer subsequently grown. Following the growth of the seed nanorods, the temperature may be decreased to, e.g., 650-750° C. for growth of an InGaN quantum well and a GaN cladding layer on the pyramidal caps of the seed nanorods. Typical parameters for InGaN quantum well growth may be a V/III ratio of 6000-10000, trimethylindium as the indium (In) source, and a total pressure of about 100 torr. An InGaN thin layer may be grown with various flows of hydrogen during the growth, e.g., with low hydrogen flow used in the beginning and larger hydrogen flow near the end of growth. The variable hydrogen flow can enable uniform distribution of the indium composition, and impede the formation of an In-rich layer at the surface of each InGaN layer. Typical parameters for the GaN cladding layer growth may be 0.5-1 minutes of undoped GaN growth followed by 1-2 minutes of Mg-doped GaN growth, both may be performed with a V/III ratio of 1500-2000, a growth temperature of 700-750° C. and a total pressure of about 100 torr. The magnesium doping can be selected to produce hole concentrations of 2−5×10¹⁷ cm⁻³.

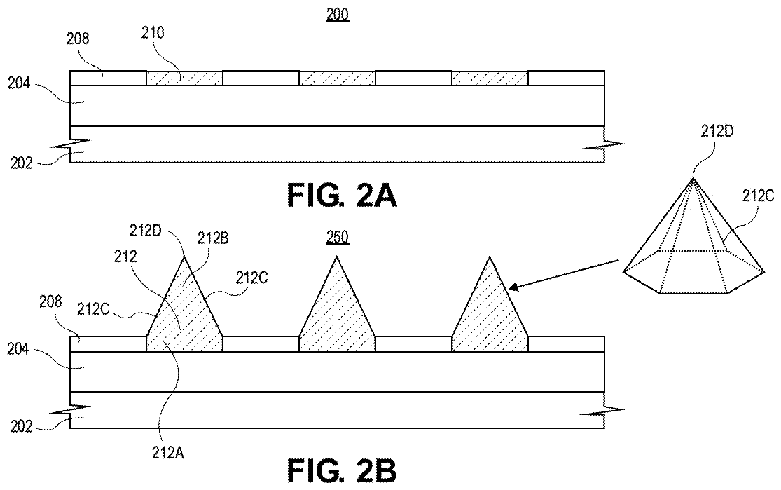

In a comparative processing scheme, FIGS. 2A and 2B illustrate cross-sectional views of operations in a comparative epitaxial growth process for fabricating nanopyramids for micro LED devices.

Referring to FIG. 2A, a starting structure 200 includes a sapphire wafer 202. Sapphire wafer 202 has a thick gallium nitride buffer layer 204 formed thereon. A dielectric mask 208 is formed to have openings therein exposing portions of the thick gallium nitride buffer layer 204. Seed N-type gallium nitride structures 210 are formed in the openings in the mask 208 (such as a silicon nitride mask). Referring to FIG. 2B, N-type gallium nitride nanopyramid structures 212 are fabricated from the N-type gallium nitride structures 210 following continued epitaxial growth to form structure 250. The nanopyramid structures 212 each include a top nanopyramid portion 212B and a seed portion 212A. The top nanopyramid portions 212B each include side facets 212C and a top point 212D. With reference to FIGS. 2A and 2B, nanopyramids formed using selective area growth has been limited to sapphire wafer substrates (which may not be economic for micro LED display production) and to very thick GaN buffers (which may not be suitable for scaling to 300 mm silicon wafers). Structures resulting from having an InGaN active layer formed on the nanopyramid structures 212 tend to have a highly non-uniform indium composition from base to the tip 212D of each nanopyramid portion 212B, which can lead to greater than 2× higher emission spectral width than desired for display applications.

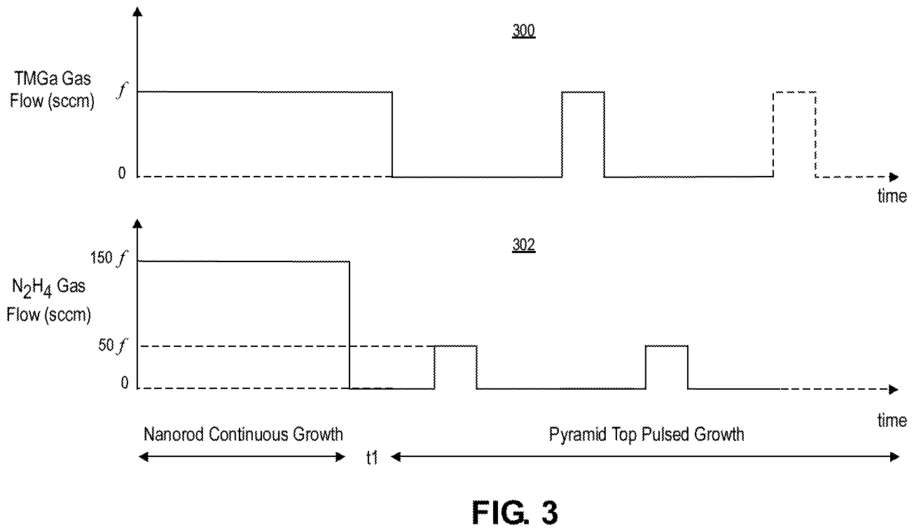

FIG. 3 includes plots 300 and 302 depicting an exemplary process for forming a plurality of truncated nanopyramids using a two-stage growth mode, in accordance with an embodiment of the present disclosure.

Referring to FIG. 3, precursor gas flow curves (including a first gas flow curve 300 and a second gas flow curve 302) are representative of a selective growth of nanorods and a subsequent pulsed growth for the formation of a truncated pyramid cap. As shown, the selective growth can be terminated by starting a pulsed growth (i.e., growth-mode-transition) at a transition time t1. The pulsed growth can further include a number of pulsed sequences, for example, a first sequence loop, a second sequence loop and/or additional sequence loops. In various embodiments, the first sequence loop can be repeated as the second sequence loop.

In an embodiment, the schematic illustration of gas flows as function of time during nanorod and pyramid top growth as depicted in FIG. 3, is representative of an exemplary embodiment for the formation of nanorods, where the first gas flow curve 300 is plotted for a first precursor gas such as trimethylgallium (TMGa) and the second gas flow curve 302 is plotted for a second precursor gas such as NH3 or N2H4. During the selective growth, GaN nanorods can be formed in a MOCVD reactor including the first precursor gas TMGa with a constant flow rate of about 10 sccm, and the second precursor gas NH3 with a constant flow rate of about 1500 sccm. That is, during the selective growth, the precursor gases (i.e., TMGa and NH3) can be flowed continuously, not pulsed (i.e., both Group III and Group V precursor gases are provided to the substrate together in a continuous, non-pulsed growth mode). Moreover, the group V precursor gas (e.g., TMGa) and group III precursor gas (e.g. NH3) can be introduced simultaneously and the group V/group III ratio can be maintained, for example, at about 100 to about 500. In an exemplary embodiment, the group V/group III ratio can be maintained at about 150. Further, other reactor conditions for the selective growth can include, for example, an initial reaction temperature of about 1010° C. to about 1060° C., a reactor pressure of about 100 Torr, and a hydrogen/nitrogen carrier gas mixture having a laminar flow of about 3000-5000 sccm.

For the pyramid cap, pulsed growth may be used. In pulsed growth, the first precursor gas such as TMGa and the second precursor gas such as NH3 or N2H4 can be introduced alternately into the growth reactor in a designed sequence, for example, shown as the first sequence loop. In various embodiments, the duration of each alternating operation within the pulsed sequence can affect the growth of the pyramid cap, which can further be optimized for specific reactor geometries. For example, in the first pulsed sequence loop, TMGa can be introduced with a flow rate of about 10 sccm for a certain period of time such as about 20 seconds followed by, for example, a 10 second carrier-gas purge (e.g., a mixture of hydrogen/nitrogen) during which no precursor gases are introduced, and followed by introducing NH3 or N2H4 with a flow rate of about 1500 sccm for a time period such as about 30 seconds followed by, for example, a 10 second carrier-gas purge (e.g., a mixture of hydrogen/nitrogen) with no precursor gases involved. Other pulse durations may also be used depending on the reactor configurations, such as for example 15-40 seconds for the Group III reactant, 15-40 seconds for the Group V reactant and 5-15 seconds for the purge gases between each reactant introduction operation.

In one embodiment, the pulsed sequence such as the first sequence loop can be repeated until a certain height and shape of the GaN truncated nanopyramid cap is reached. For example, the sequence loop can be repeated as the second sequence loop, the third sequence loop (not illustrated) and so on. In each sequence loop, the group V precursor gas (e.g., TMGa) and group III precursor gas (e.g. NH3 or N2H4) can have an effective V/III ratio in a range of, for example, from about 60 to about 300. In various embodiments, the temperature, reactor pressure, and carrier gas flow for the pulsed growth can remain at their same settings as for the selective growth. One of ordinary skill in the art will understand that the disclosed growth parameters are exemplary and can vary depending on the specific reactor used.

With particular reference to FIGS. 1A-1B and 3, embodiments of the present invention may include or exhibit one or more of: (1) a thin nucleation layer on Si(111), (2) nanometer scale nanorods, (3) truncated nanopyramids, (4) uniform indium composition in an InGaN quantum well layer, and/or (5) a high quality InGaN active layer. Benefits or advantages to implementing one or more of the embodiments described herein may include one or more of: (1) enabling scaling to 300 mm silicon wafers, (2) the fabrication of structures having high quality GaN nanorods and “truncated” nanopyramids, (3) high and uniform indium composition along the truncated nanopyramid nonpolar facets, and on the top c-plane facet, (4) enabling pure and efficient red and green color emission, (5) achieving uniform indium composition in the InGaN layer, and/or (6) high efficiency red and green micro LEDs, which results in low power display.

In an embodiment, to enable selective area epitaxy and growth of truncated nanopyramids, a mask layer having a plurality nano-holes formed therein may be formed on a transition metal nitride nucleation layer. The mask layer may be formed of an insulating material including, but not limited to, silicon oxide (for example, silicon dioxide (SiO2)) or silicon nitride, titanium dioxide (TiO₂), Si₃N4, Al₂O₃, titanium nitride (TiN), zirconium dioxide (ZrO2), titanium aluminum nitride (TiAlN), titanium silicon nitride (TiSiN), or the like. This is followed by etching the mask layer in a desired nano-hole pattern by performing a lithography process. A nano-hole may have a cross-sectional shape, including shapes including but not limited to circles, ovals, polygons, or the like. The shape of the nanostructures is defined by the shape of the nano-hole. The nanostructures may be formed as a hexagonal pyramid, for example.

Embodiments described herein may include or exhibit one or more of the following features: a micro LED display including an array of red, green, and blue micro LEDs, where each micro LED includes a plurality of GaN truncated nanopyramids connected in parallel (i.e., all anodes are connected to one terminal, and all cathodes are connected to one terminal). Each GaN truncated nanopyramid can include an N-type GaN truncated pyramid top. A singular or a plurality of InGaN active layer and undoped GaN barrier alternating layers (e.g., multi quantum wells) can be formed on the truncated nanopyramids. The outmost undoped GaN barrier layer can be covered by thin p-type layer including gallium and nitrogen (such as a p-GaN layer or a p-AlGaN layer) electron blocking layer, on which a p-GaN cladding layer can be grown. Each InGaN active layer can have a uniform indium composition along the pyramid cap facets extending from the base of the pyramid cap to the truncated top of the pyramid cap. The indium composition in the InGaN can take a value from 20% to 50% corresponding to different primary color (red, green, or blue). The InGaN active layer can be grown using pulsed-mode epitaxy where a purge pulse of hydrogen/nitrogen mix is flown in between the indium, gallium, and nitrogen sources to make sure the indium composition is uniform along the r-plane of the pyramid cap. The n-GaN pyramid cap can be grown on an N-GaN nanorod that has been grown epitaxially inside a trench (e.g., 50 nm wide) of a dielectric mask (e.g., Si₃N₄) using selective MOCVD growth. The N-type GaN nanorod can be grown epitaxially seeded from a nucleation layer composed of transition metal nitride (e.g. NbN, TiN, HfN, ZrN, or the like). The thin (e.g., 25 nm) nucleation layer can be deposited on a thin (e.g., 25 nm) AIN barrier layer which can be grown epitaxially on Si(111) wafer substrate. The truncated nanopyramid cap can be grown using continuous mode or pulsed mode MOCVD epitaxy at a suitable temperature (e.g., less than 1000° C.) to produce a truncated top hexagonal pyramid. A gallium precursor can be TMGa and a nitrogen precursor can be ammonia or hydrazine.

Embodiments described herein may be directed to structures having a p-type ZnO as a cladding layer in place of or together with p-type GaN (e.g., a thin p-GaN and a thick p-ZnO contact). Embodiments described herein may be directed to structures having a plurality of pyramids used to fabricate a single micro LED (e.g., with size of approximately 4 microns (such as 23 nanopyramids per 4 micron×4 micron region). Embodiments described herein may be directed to structures having a diameter size of the hole and pitch of pyramids to change an emitted color. Embodiments described herein may be directed to structures having monolithic green and blue LEDs and/or pixels. Embodiments described herein may be directed to structures having monolithic red, green, and blue LEDs and/or pixels.

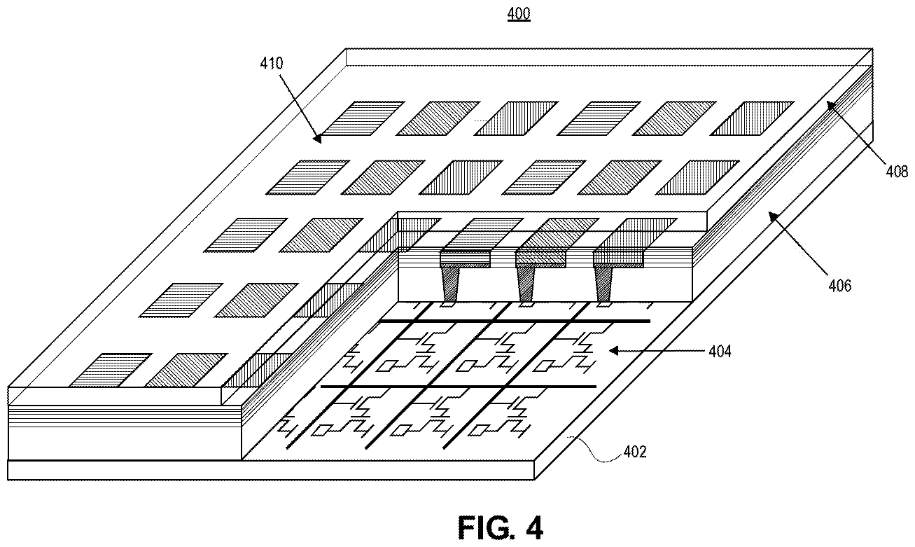

As an exemplary display architecture, FIG. 4 illustrates a schematic of micro LED display architecture, in accordance with an embodiment of the present disclosure. Referring to FIG. 4, a micro LED display 400 includes a backplane 402 having pixel circuits 404 thereon. An insulator 406 is over the pixel circuits 404. Micro LED layers 408 are included over the insulator 406. A transparent electrode 410 is over the micro LED layers 408.

It is to be appreciated that, in contrast to one or more embodiments described herein, state of the art approaches involve fabricating discrete red, green, and blue μLEDs on separate wafers and then transferring the μLEDs using pick and place assembly to the display backplane. Such state of the art solutions are associated with high manufacturing cost due to the slow transfer rate of three types of μLEDs sequentially from source wafers to backplane. In addition, since three sequential transfers are needed, the probability of missing transfers increases and can result in low yield. This may be particularly impactful for displays used in smartphones (e.g., diagonal=5.1 inches), converged mobility tablets (e.g., diagonal=7 inches), and mobile notebooks (e.g., diagonal=11.6 inches−13.3 inches).

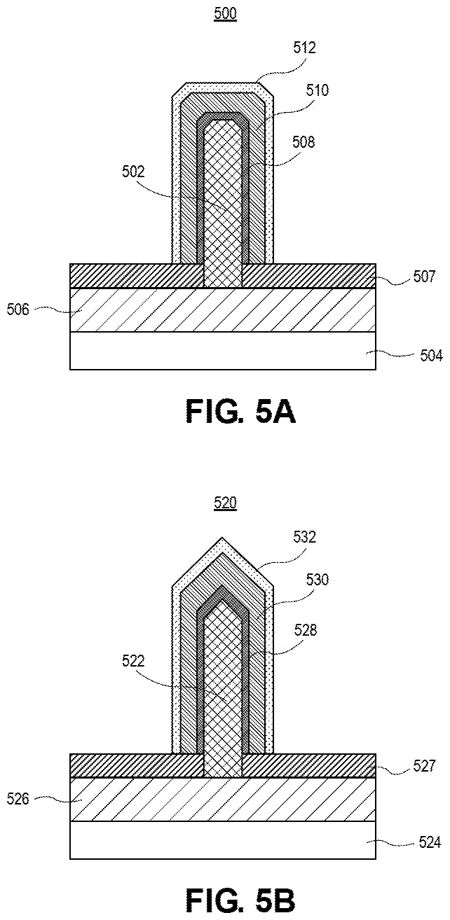

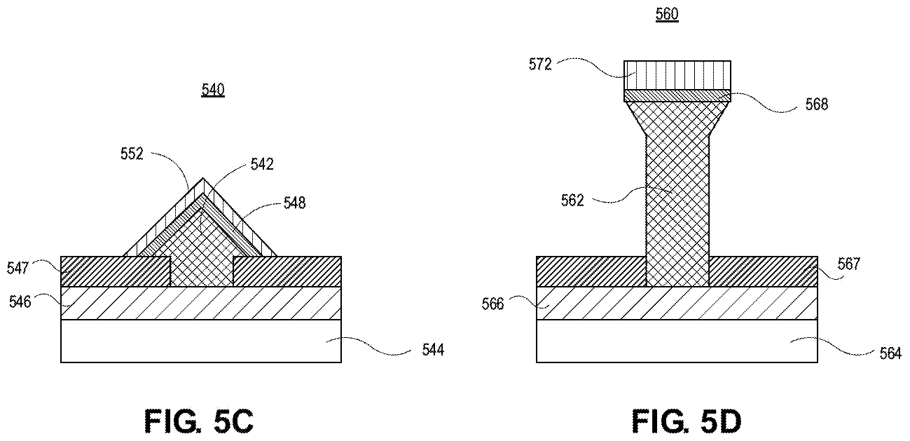

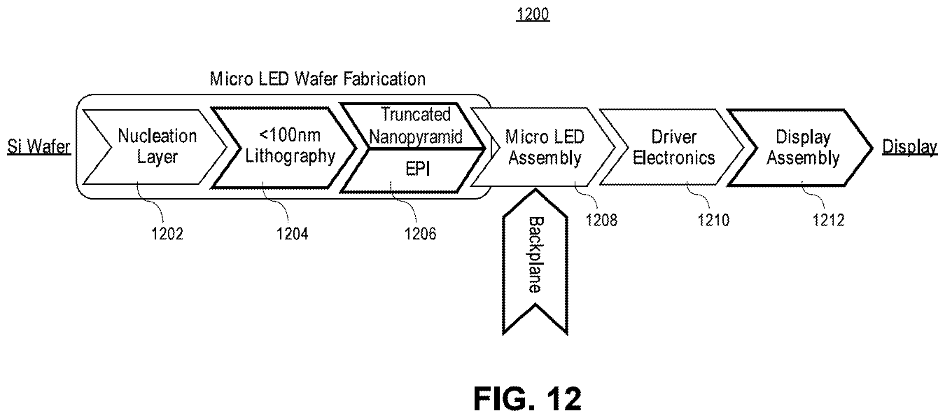

In another aspect, micro LEDs can be co-axial (core-shell) truncated nanopyramid structures, nanowire structures, nanopyramid structures, or axial nanowire structures, examples of which are described below in association with FIGS. 5A-5D. An exemplary fabrication scheme is described below in association with FIG. 12.

FIGS. 5A-5D illustrate options for micro LED structures, with an emphasis on a truncated nanopyramid structure in accordance with embodiments described herein. For example, FIG. 5A illustrates a cross-sectional view of a GaN truncated nanopyramid based LED highlighting certain layers of the LED, in accordance with an embodiment of the present disclosure. In a particular embodiment, an LED 500 includes an n-type GaN truncated nanopyramid 502. The GaN truncated nanopyramid 502 is above a substrate 504, which may be a Si(111) substrate. An intervening nucleation layer 506 has an opened mask layer 507 thereon. In one embodiment, the n-type GaN truncated nanopyramid 502 has a diameter in the range of 25-75 nanometers. In one embodiment, the n-type GaN truncated nanopyramid 502 is formed on a MN/AlN nucleation layer 506 layer with MN=metal nitride, and where the metal can be Ti, Hf, Nb, etc. An active layer 508 of InGaN is on the n-type GaN truncated nanopyramid 502. A p-GaN cladding layer 510 is included on the active layer 508. A conductive electrode layer 512 may be formed on the p-GaN cladding layer 510, as is depicted. It is to be appreciated that a micro LED may be composed of multiple truncated nanopyramids connected in parallel. For example, a 5 micron×5 micron micro LED may be composed of, e.g., 20 truncated nanopyramids.

As a comparative example differentiated from the truncated nanopyramid-based LED of FIG. 5A, FIG. 5B illustrates a cross-sectional view of a GaN nanowire based LED highlighting certain layers of the LED. In a particular example, an LED 520 includes, an n-type GaN nanowire 522. The GaN nanowire 522 is above a substrate 524, which may be a Si(111) substrate. An intervening nucleation layer 526 has an opened mask layer 527 thereon. In one embodiment, the n-type GaN nanowire 522 has a diameter in the range of 100-200 nanometers, and a height in the range of 1-10 microns. An active layer 528 of InGaN is on the n-type GaN nanowire 522. A p-GaN cladding layer 530 is included on the active layer 528. A conductive electrode layer 532 may be formed on the p-GaN cladding layer 530, as is depicted. It is to be appreciated that a micro LED may be composed of multiple nanowires connected in parallel. For example, a 5 micron×5 micron micro LED may be composed of, e.g., 20 nanowires.

As another comparative example differentiated from the truncated nanopyramid-based LED of FIG. 5A, FIG. 5C illustrates a cross-sectional view of a nanopyramid or micropyramid based LED highlighting certain layers of the LED. In a particular example, an LED 540 includes an n-GaN nanopyramid 542 above a substrate 544, which may be a Si(111) substrate. An intervening nucleation layer 546, such as described for FIG. 5A, has an opened mask layer 547 thereon. An active layer 548, such as described for FIG. 5A, is included on the n-GaN nanopyramid 542. A p-type cladding layer 552, such as described for FIG. 5A, is included on the active layer 548. It is to be appreciated that a micro LED may be composed of multiple nanopyramids connected in parallel. For example, a 5 micron×5 micron micro LED may be composed of, e.g., 20 nanopyramids.

As another comparative example differentiated from the truncated nanopyramid-based LED of FIG. 5A, FIG. 5D illustrates a cross-sectional view of an axial nanowire based LED highlighting certain layers of the LED. In a particular embodiment, an LED 560 includes an n-GaN axial nanowire 562 above a substrate 564, which may be a Si(111) substrate. An intervening active layer 566, such as described for FIG. 5A, has an opened mask layer 567 thereon. An active layer 568, such as described for FIG. 5A, is included on the n-GaN axial nanowire 562. A p-type cladding layer 572, such as described for FIG. 5A, is included on the active layer 568.

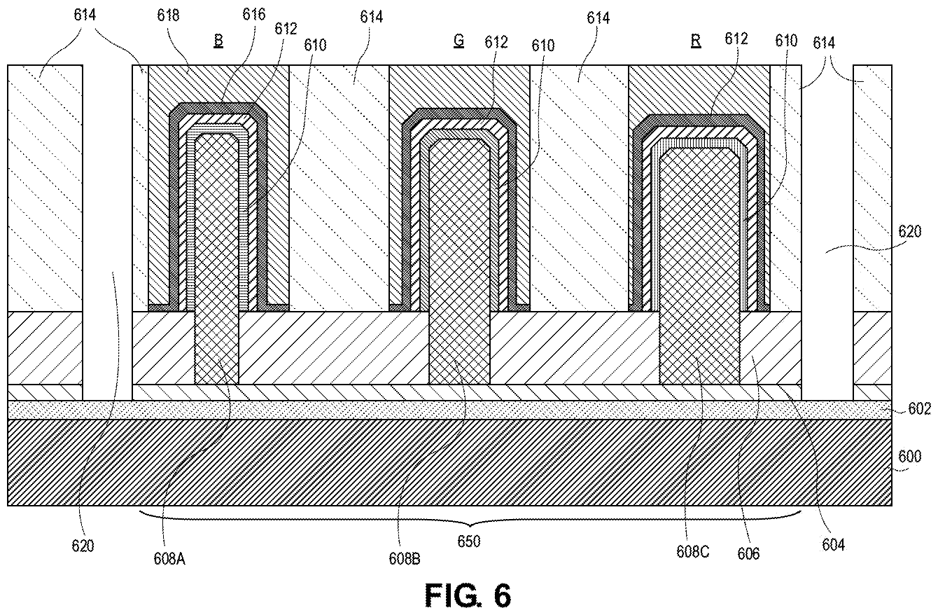

It is to be appreciated that a combination of LED colors based on varying truncated nanopyramid sizes can be included on a common substrate. As an example, FIG. 6 illustrates a cross-sectional view of an RGB chip with three truncated nanopyramid based LEDs, in accordance with an embodiment of the present disclosure.

Referring to FIG. 6, although shown as three different color micro-LEDs across (e.g., blue (B), green (G), red (R) from left-right), the three are shown in this manner for illustrative purposes only. It is to be appreciated that for a pixel such as a 2 x 2 pixel element, only two micro LEDs would be viewable for a given cross-section. It is to be appreciated that a variety of arrangements of micro LEDs may be suitable to make a single pixel. In one embodiment, three micro LEDs are arranged side-by-side, as depicted in FIG. 6. In another embodiment, four micro LEDs are arranged a 2 x 2 arrangement. In another embodiment, nine micro LEDs are arranged a 3 x 3 arrangement, etc.

With reference again to FIG. 6, in a particular embodiment, a source micro LED wafer 600 (such as a silicon wafer) has “RGB Chips” monolithically grown thereon. The silicon wafer 600 is first coated with aluminum nitride (AlN) buffer layer 602, e.g., having a thickness of approximately 50 nanometers. The A1N buffer layer 602 may have a bandgap of about 6 eV and may be transparent to infrared radiation. A metal-based nucleation layer (MNL) 604 is then deposited on the AlN buffer layer 602. The MNL 604 may have a thickness in the range of 50-100 nm and may be crystalline or polycrystalline. A silicon nitride mask 606 is then deposited on the MNL 604. Lithography may then be used to open holes in the silicon nitride mask 606 mask with diameters carefully chosen to accommodate the subsequent formation of LEDs that emit red, green, and blue colors. GaN truncated nanopyramid cores are then grown, e.g., by metal organic chemical vapor deposition (MOCVD), as seeded from the MNL 604. In an embodiment, the truncated nanopyramid cores have diameters in the range 30 nm to 200 nm.

Referring again to FIG. 6, indium gallium nitride (InGaN) shells 610 are grown around the GaN cores 608, e.g., using MOCVD. The amount of indium in the InGaN shells 610 depends on the GaN core diameter. In an embodiment, smaller core diameter result in the growth of InGaN shells with smaller indium content. Larger core diameters result in the growth of InGaN shells with larger indium content. For blue (B) color 608A emission, the indium content is approximately 20% (of In and Ga). For green (G) color 608B emission, the indium content is approximately 35% (of In and Ga). For red (R) color 608C emission, the indium content is approximately 50% (of In and Ga). A p-type GaN cladding layer 612 may then be formed around the InGaN shells 610, e.g., using MOCVD. The core-shell truncated nanopyramids are then covered by an insulating material layer 614, e.g., a silicon oxide (SiOx) layer. A lithography and etch may then be used to expose the p-GaN cladding layers 612 for all color core-shell truncated nanopyramid structures. Atomic layer deposition may then be used to conformally deposit a metal layer 616 on the p-GaN cladding layers 612. A metal fill process may then be performed to fill in contact metals 618 for the three color LED structures.

With reference again to FIG. 6, in accordance with an embodiment of the present disclosure, a light-emitting diode structure includes a GaN truncated nanopyramid above a substrate, and an InGaN active layer over the GaN truncated nanopyramid. In one embodiment, the InGaN active layer is an approximately Ino.2Gao.8N material layer, and the light-emitting diode structure is a blue-emitting diode structure. In one embodiment, the InGaN active layer is an approximately Ino.35Gao.65N material layer, and the light-emitting diode structure is a green-emitting diode structure. In one embodiment, the InGaN active layer is an approximately Ino.5Gao.5N material layer, and the light-emitting diode structure is a red-emitting diode structure. In one embodiment, the light-emitting diode structure further includes a cladding layer over the InGaN active layer, the cladding layer including gallium and nitrogen. In one embodiment, the GaN truncated nanopyramid is N-type, and the cladding layer is P-type.

Referring more generally to FIG. 6 and a 2×2 pixel arrangement, a semiconductor structure includes a silicon wafer 600 and plurality of pixel elements 650. Each of the pixel elements 650 includes a first color truncated nanopyramid LED, a second color truncated nanopyramid LED (the second color different than the first color), and a pair of third color truncated nanopyramid LEDs (the third color different than the first and second colors). A continuous insulating material layer 614 is laterally surrounding the first color truncated nanopyramid LED, the second color truncated nanopyramid LED, and the pair of third color truncated nanopyramid LEDs. Adjacent pixel elements are separated from one another by a trench 620 between corresponding continuous insulating material layers 614.

In an embodiment, for each of the pixel elements 650, the first color is red, the second color is green, and the third color is blue. In another embodiment, for each of the pixel elements 650, the first color is red, the second color is blue, and the third color is green. In another embodiment, for each of the pixel elements 650, the first color is blue, the second color is green, and the third color is red. In an embodiment, for each of the pixel elements 650, the first color truncated nanopyramid LED, the second color truncated nanopyramid LED, and the pair of third color truncated nanopyramid LEDs have a 2×2 arrangement from a plan view perspective.

In an embodiment, for each of the pixel elements 650, the first color truncated nanopyramid LED, the second color truncated nanopyramid LED, and the pair of third color truncated nanopyramid LEDs include gallium nitride (GaN) cores. In an embodiment, for each of the pixel elements 650, the first color truncated nanopyramid LED, the second color truncated nanopyramid LED, and the pair of third color truncated nanopyramid LEDs include indium gallium nitride (InGaN) shells. In an embodiment, for each of the pixel elements 650, the continuous insulating material layer includes silicon oxide or carbon-doped silicon dioxide.

Different from the structure of FIG. 6, it is to be appreciated that hybrid structures may also be fabricated. In one such embodiment, green and blue LEDs are nanowires (e.g., core-shell or axial nanowires) and the red LED is a truncated nanopyramid. Other combinations are also contemplated within the spirit and scope of the present disclosure.

In another aspect, other truncated nanopyramid-based LEDs for micro LED displays are described. The fabrication of LEDs with high power efficacies for three color LED emitters may enable power reductions with micro LED displays. In an embodiment, a device structure (e.g., truncated nanopyramid LED), and a process technology to fabricate a device structure that has high power efficacy for red, green and blue color emitters at the same time is described.

Advantages to implementing one or more embodiments described herein include one or more of (1) enabling a “direct transfer method” for mass transfer of micro LEDs from source wafer to display backplane with high yield and low manufacturing cost, (2) high light extraction efficiency with lower power consumption, (3) control of a radiation pattern from a micro LED to the observer, and/or (4) realizing the promised power reductions with micro LED displays based on the fabrication of LEDs with high power efficacies for the three color LED emitters.

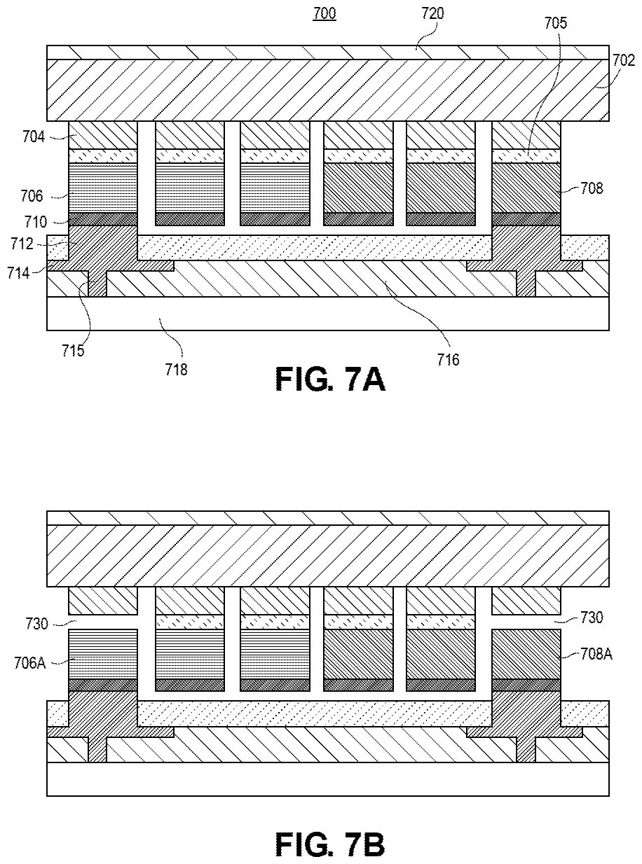

FIG. 7A illustrates a cross-sectional view of assembly components (e.g., micro LED wafer and display backplane) during “selective bonding” of micro LEDs, in accordance with an embodiment of the present disclosure.

Referring to FIG. 7A, an LED substrate 702, such as a silicon wafer, has a patterned growth or nucleation layer 704 thereon, such as a patterned aluminum nitride layer. Individual micro LEDs 706/708 are associated with each pattern feature of the patterned growth or nucleation layer 704. In one embodiment, a first group of one type of micro LEDs 706, such as blue micro LEDs, is adjacent a second group of micro LEDs 708, such as green micro LEDs. A release layer 705, such as a metal nitride layer, may be between the individual micro LEDs 706/708 and the associated pattern feature of the patterned growth or nucleation layer 704, as is depicted. A metal bonding layer 710, such as a copper or aluminum layer, is on each of the individual micro LEDs 706/708. A backplane 718 is opposite the LED substrate 702. The backplane 718 may include a dielectric layer 716 having conductive features therein. The conductive features may include reflective plates 714 and associated vias 715. Metal pads or bumps 712 are on the reflective plates 714. In an embodiment, metal bonding layer 710 is a copper layer and metal pads or bumps 712 are copper pads or bumps. In another embodiment, metal bonding layer 710 is an aluminum layer and metal pads or bumps 712 are aluminum pads or bumps. Selected ones of the individual micro LEDs 706/708 are bonded to a corresponding metal pads or bumps 712 to provide a micro LED wafer bonded to a display backplane. An anti-reflective coating 720 is formed on the LED substrate 702.

FIG. 7B illustrates a cross-sectional view of assembly components (e.g., micro LED wafer and display backplane) during “selective release” of micro LEDs, in accordance with an embodiment of the present disclosure. The LED substrate 702 is then released from the display backplane 718 upon removal of release layer 705 at locations 730 of the selected ones of the individual micro LEDs 706/708. The selective release leaves micro LEDs 706A and 708A remaining as bonded to the display backplane 718. The remaining micro LEDs on LED substrate 702 may then be bonded to another display back plane.

In another aspect, in an embodiment, a two-operation process for transferring micro LEDs from silicon wafer to display backplane is disclosed, such as described in association with FIGS. 7A and 7B. First, selective bonding is performed using thermo-compression bonding (TCB). Next, selective release of micro LEDs is performed using backside (silicon side) irradiation with infra-red laser with wavelength>1300 nm. In another embodiment, a blanket release and selective bond approach is described as a two-operation process for transferring micro LEDs from a silicon wafer to a display backplane. First, blanket release of all micro LEDs is performed using “front-side” irradiation with infra-red laser with wavelength>1000 nm. Next, selective bonding of micro LEDs is performed using TCB, followed by mechanical removal of micro LEDs. from the silicon wafer.

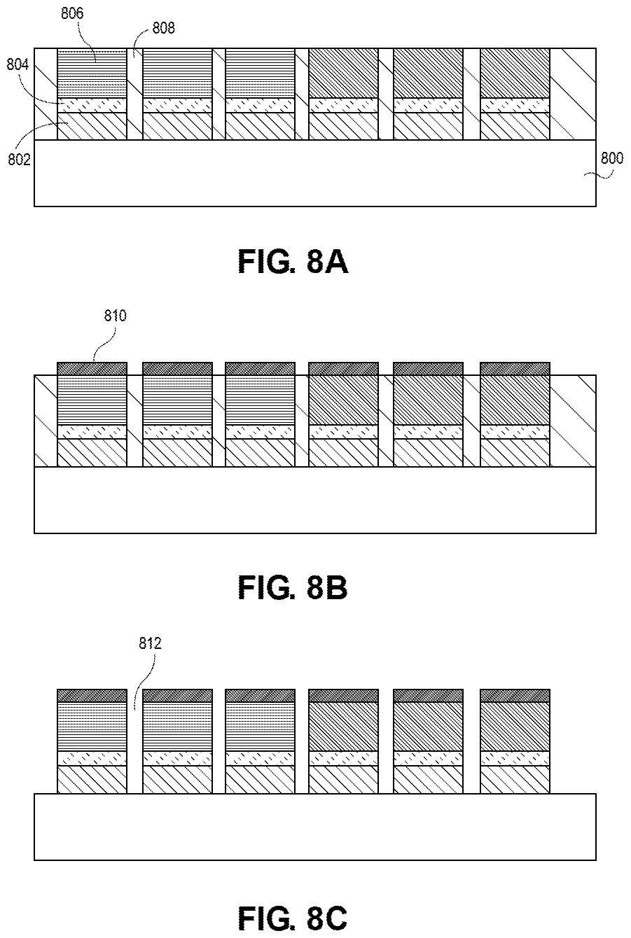

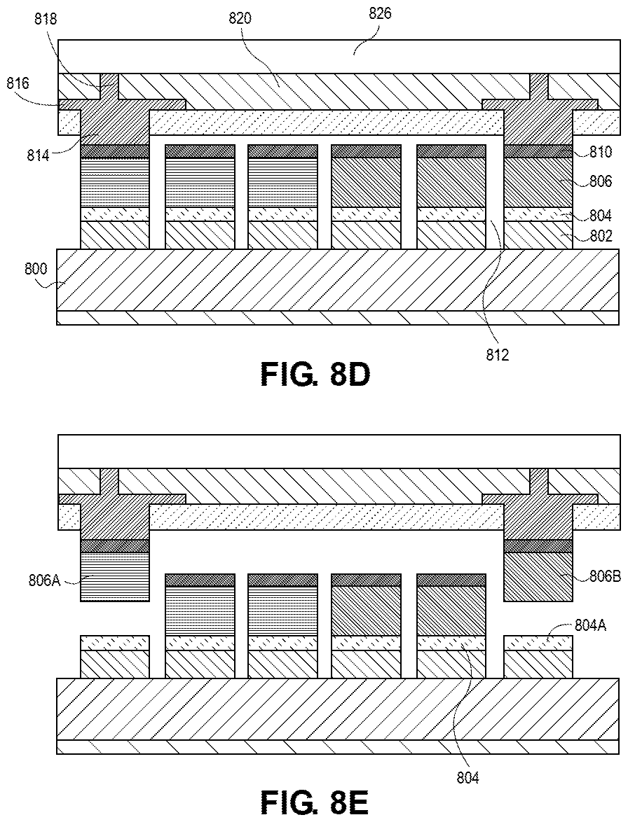

As an example of a blanket release approach, FIGS. 8A-8E illustrate cross-sectional views of various operations in a method of assembling a micro LED display, in accordance with an embodiment of the present disclosure.

Referring to FIG. 8A, an LED substrate 800, such as a silicon wafer, has a patterned growth or nucleation layer 802 thereon, such as a patterned aluminum nitride layer. Individual micro LEDs 806 are associated with each pattern feature of the patterned growth or nucleation layer 802. A release layer 804, such as a metal nitride layer, may be between the individual micro LEDs 806 and the associated pattern feature of the patterned growth or nucleation layer 802, as is depicted. An insulating layer 808 surrounds the micro LEDs 806.

In an embodiment, “blanket release” of micro LEDs is performed by irradiation (e.g., through the wide-bandgap micro LEDs) with infra-red laser with a wavelength>1000 nm. The release layer (transition metal nitride) absorbs the infra-red radiation and bonds between the release layer and micro LEDs become very weak.

Referring to FIG. 8B, a metal bonding layer 810, such as a copper or aluminum layer, is formed as a pad on each of the individual micro LEDs 806. The insulating layer 808 is then removed, as depicted in FIG. 8C.

Referring to FIG. 8D, a backplane 826 is positioned opposite the substrate 800. The backplane 826 includes a dielectric layer 820 having conductive features therein. The conductive features may include reflective plates 816 and associated vias 818. Metal pads or bumps 814 are on the reflective plates 816. Mechanical separation of the micro LEDs from silicon wafer is then performed, as is depicted in FIG. 8E. Referring to FIG. 8E, release occurs at location labeled 804A, 806A and 806B.

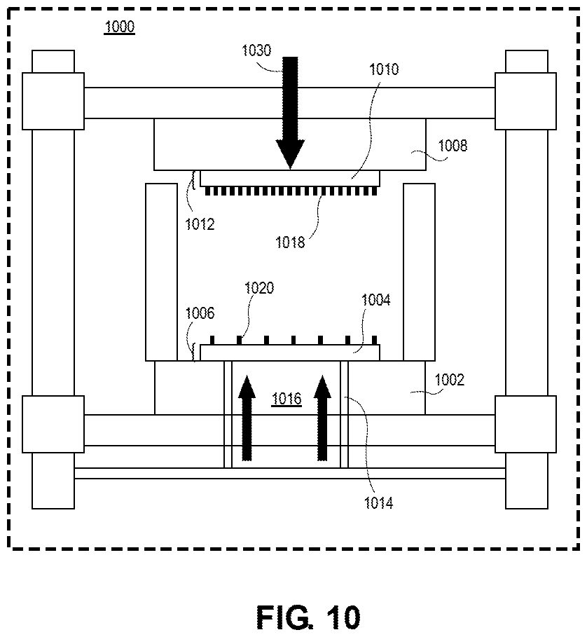

It is to be appreciated that, as contemplated for embodiments described herein, typically, a plurality of micro LEDs with different colors that have been grown on a single wafer monolithically is ultimately transferred to the display backplane. The scope is thus not limited to transferring “RGB chips”. It is also to be appreciated that the above bonding approaches may be performed in a bonder too such as tool 1000 described above in association with FIG. 10.

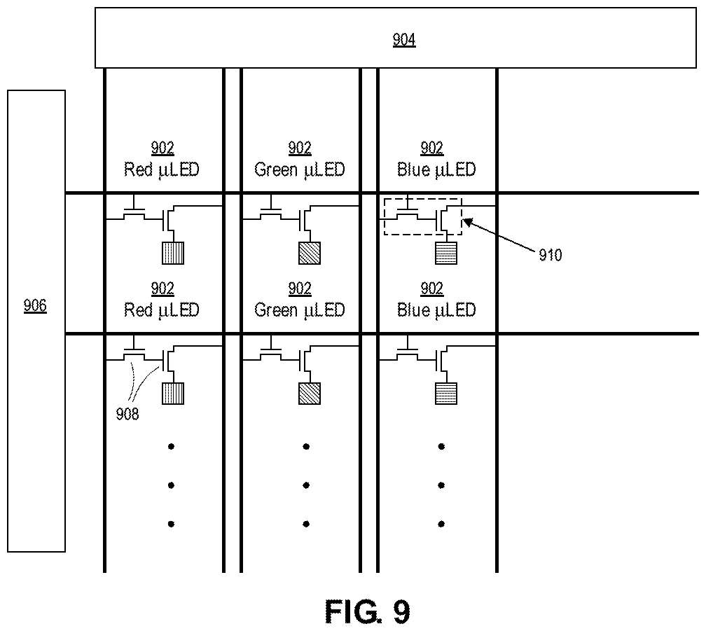

FIG. 9 is a schematic illustration of a micro LED display architecture, in accordance with an embodiment of the present disclosure. Referring to FIG. 9, micro LEDs 902 are arranged in a matrix. The micro LEDs are driven through “Data Driver” 904 and “Scan Driver” 906 chips. Thin film transistors 908 are used to make “pixel driver circuits” 910 for each micro LED. In an embodiment, the micro LEDs are fabricated on a silicon wafer then transferred to a glass substrate called “backplane” where the “pixel driver circuits” 910 have been fabricated using thin film transistors.

It is to be appreciated that, in a typical display, each pixel includes Red, Green and Blue (RGB) subpixels controlled independently by a matrix of transistors. For a μLED display, individual, small LED chips are used as the sub-pixel. Unlike organic LEDs (OLEDs), inorganic LEDs require high processing temperatures (e.g., greater than 1000° C.) and cannot be “grown” and patterned directly on top of a transistor matrix. In most cases, the micro LED chips are therefore manufactured separately and then positioned and connected to the transistor matrix via a pick and place process. Volume production at costs compatible with target applications still faces multiple engineering and manufacturing challenges. Such challenges may include LED epitaxy quality and homogeneity, efficiency of very small μLEDs, sidewall effects, massively parallel chip transfer technologies (e.g., pick and place) with position accuracy and high throughput, cost, handling of small die, etc., interconnects, color conversion, defect management, supply chain, and/or cost of production.

It is also to be appreciated that, like OLED, μLED technology is an emissive display technology. However, due to the inorganic nature of the emitting materials, their efficiency and narrow emission bands, μLEDs also offer the prospect of significantly improved performance in terms of energy consumption, color gamut, brightness, contrast (High Dynamic Range), long lifetime and environmental stability (e.g., no or low sensitivity to air and moisture), and/or compatibility with flexible backplane technologies to enable curved or flexible displays.

In a particular embodiment, upon fabrication of a micro-LED wafer, in order to fabricate a micro-LED based display, a transfer method is used in which micro-LEDs are transferred from a source wafer to a carrier wafer and then bonded with a target display backplane with the assistance of precise alignment, thermal compression bonding and selective release using an infra-red (IR) source as a source to release select one of the LEDs. In an example, FIG. 10 illustrates a cross-sectional view of a schematic of a display bonder apparatus, in accordance with an embodiment of the present disclosure.

Referring to FIG. 10, a display bonder apparatus 1000 includes a first support 1002 for holding a display backplane substrate 1004 in a first position 1006. A second support 1008 is for holding a silicon wafer 1010 in a second position 1012. The second position 1012 is over the first position 1006. In one embodiment, a piston 1014 is coupled to the first support 1002. The piston 1014 is for moving the display backplane substrate 1004 from the first position 1006 toward the second position 1012. Further, the piston 1014 applies a force 1016 to the display backplane substrate 1004 to bond light-emitting diode (LED) pixel elements 1018 on the silicon wafer 1010 to metal bumps 1020 on the display backplane substrate 1004. In an embodiment, the display bonder apparatus further includes an infra-red (IR) irradiation source 1030 coupled to the second support 1008.

In an embodiment, the display bonder apparatus 1000 is used in a transfer process where a micro LED source wafer is brought into contact with a display substrate having metal bumps, such that the micro LED metal contacts and backplane metal bumps are opposite to one another. The bonding process involves orienting the two substrates (source wafer and display substrate) parallel to one another and compressing the two substrates together by applying force 1016 on the outer surface of the display substrate. The force 1016 may be applied to the center of the display substrate with a piston-type mechanism. The bonder apparatus 1000 may provide precise bonding and may be suitable for bonding one substrate pair at a time. The bonding apparatus may be provided with a vacuum chamber (or any controlled atmosphere) and an aligner. The substrates may be aligned in the aligner, loaded in the controlled atmospheric chamber (vacuum/other), and thereafter bonded to each other.

In one embodiment, after bonding, the micro LEDs are selectively released from the silicon wafer to the display backplane. The selective release is carried out using infra-red (IR) laser irradiation through the silicon substrate (i.e., silicon is transparent to infra-red light). In a specific embodiment, the micro LEDs have a dimension of approximately 5 microns. In such an embodiment, in order to release only the micro LEDs that have been bonded to the backplane, a laser beam with a spot size as small as approximately 5 μm may need to be used.

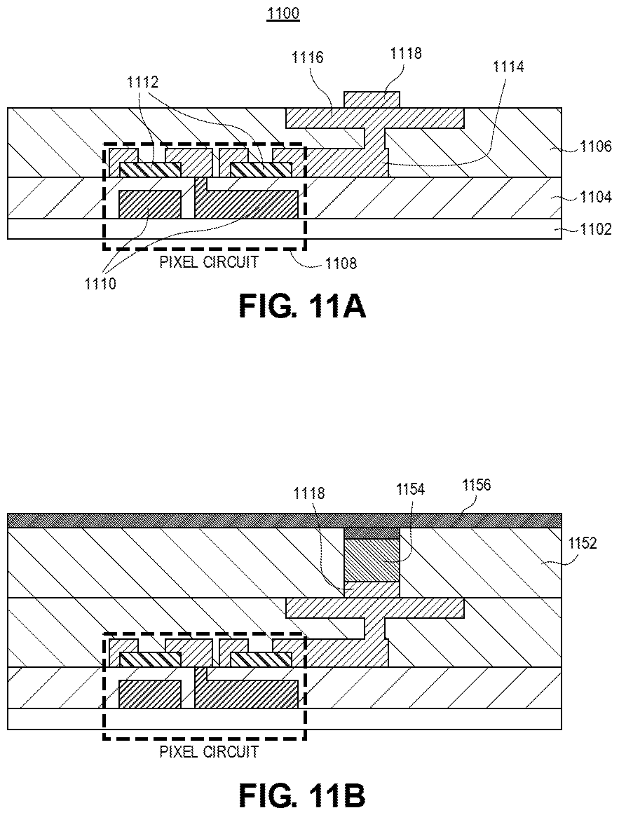

In accordance with an embodiment of the present disclosure, a method and structure for receiving a micro device on a receiving substrate are disclosed. Micro LEDs may be bonded to a backplane that has protrusions of electrically conductive pads that are sitting on a large light reflective metallic plate, as depicted in FIG. 11A. It is to be appreciated that traditional technologies for transferring of devices include transfer by wafer bonding from a transfer wafer to a receiving wafer. One such implementation is “direct printing” involving one bonding operation of an array of devices from a transfer wafer to a receiving wafer, followed by removal of the transfer wafer. By contrast, embodiments described herein involve the direct bonding of micro LEDs on a display backplane followed be selective removal of the micro LEDs (as opposed to removing the whole wafer).

FIG. 11A illustrates a cross-sectional view of a display backplane prior to having micro LEDs bonded thereon, in accordance with an embodiment of the present disclosure.

Referring to FIG. 11A, a backplane structure 1100 includes a glass substrate 1102 having an insulating layer 1104 thereon. A planarization oxide layer 1106 may be on the insulating layer 1104. Pixel thin film transistor (TFT) circuits 1108 are included in and on the insulating layer 1104. Each of the pixel TFT circuits 1108 includes gate electrodes 1110, such as metal gate electrodes, and channels 1112. A portion of the insulating layer 1104 may act as a gate dielectric for each of the pixel TFT circuits 1108.

In an embodiment, the pixel TFT circuits 1108 are low temperature polysilicon (LTPS)-type TFTs. In another embodiment, the pixel TFT circuits 1108 are IZGO TFTs or IGZO-type TFTs, where the channel 1112 of each of the pixel TFT circuits 1108 includes a semiconducting oxide material. In an embodiment, the semiconducting oxide material is an IGZO layer that has a gallium to indium ratio of 1:1, a gallium to indium ratio greater than 1 (e.g., 2:1, 3:1, 4:1, 5:1, 6:1, 7:1, 8:1, 9:1, or 10:1), ora gallium to indium ratio less than 1 (e.g., 1:2, 1:3, 1:4, 1:5, 1:6, 1:7, 1:8, 1:9, or 1:10). A low indium content IGZO may refer to IGZO having more gallium than indium (e.g., with a gallium to indium ratio greater than 1:1), and may also be referred to as high gallium content IGZO. Similarly, low gallium content IGZO may refer to IGZO having more indium than gallium (e.g., with a gallium to indium ratio less than 1:1), and may also be referred to as high indium content IGZO. In another embodiment, the semiconducting oxide material is or includes a material such as tin oxide, antimony oxide, indium oxide, indium tin oxide, titanium oxide, zinc oxide, indium zinc oxide, gallium oxide, titanium oxynitride, ruthenium oxide, or tungsten oxide.

In an embodiment, the semiconducting oxide material is an amorphous, crystalline, or semi crystalline oxide semiconductor, such as an amorphous, crystalline, or semi crystalline oxide semiconductor IGZO layer. The semiconducting oxide material may be formed using a low-temperature deposition process, such as physical vapor deposition (PVD) (e.g., sputtering), atomic layer deposition (ALD), or chemical vapor deposition (CVD). The ability to deposit the semiconducting oxide material at temperatures low enough to be compatible with back-end manufacturing processes represents a particular advantage. The semiconducting oxide material may be deposited on sidewalls or conformably on any desired structure to a precise thickness, allowing the manufacture of transistors having any desired geometry.

In an embodiment, gate electrodes 1110 includes at least one P-type work function metal or N-type work function metal. For a P-type transistors, metals that may be used for the gate electrode 1110 may include, but are not limited to, ruthenium, palladium, platinum, cobalt, nickel, and conductive metal oxides (e.g., ruthenium oxide). For an N-type transistor, metals that may be used for the gate electrode 1110 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

The planarization oxide layer 1106 may have conductive features therein. The conductive features may include one or more interconnects 1114 and associated reflective plate or mirror 1116. Metal pads or bumps 1118 are on the reflective plate or mirror 1116. In an embodiment, metal pads or bumps 1118 are copper or aluminum pads or bumps. The structure of FIG. 11A may be referred to as a back plane.

A micro LED may be bonded to the backplane structure of FIG. 11A. In an example, FIG. 11B illustrates a cross-sectional view of a display backplane having a micro LED bonded thereon, in accordance with an embodiment of the present disclosure.

Referring to FIG. 11B, a front plane includes a micro LED 1154 bonded to a corresponding metal pads or bumps 1118 coupled to the back plane of FIG. 11A. A second planarization oxide or insulating layer 1152 may be formed to surround the bonded structure. A transparent electrode 1156, such as an indium tin oxide (ITO) layer, is formed thereon with a window exposing the micro LED 1154. The transparent electrode 1156 may function as a common cathode. In an embodiment, the micro LED 1154 is a green micro LED, a blue micro LED, or a red micro LED.

In another aspect, FIG. 12 is a flow diagram 1200 illustrating an RGB display production process, in accordance with an embodiment of the present disclosure. Referring to flow diagram 1200, at operation 1202, a Si wafer has a nucleation layer formed thereon, such as an AlN nucleation layer, and metal nitride/AlN nucleation layer or a GaAs nucleation layer. At operation 1204, sub 100 nanometer lithography is used to pattern a layer on the nucleation layer, or to pattern the nucleation layer. At operation 1206, truncated nanopyramid growth is performed on the nucleation layer, e.g., by epitaxial deposition. At operation 1208, a backplane is introduced into the micro LED assembly process. At operation 1210, driver electrons are fabricated. At operation 1212, display assembly is performed to finally provide a display.

Advantages of implementing one or more embodiments described herein may include, but need not be limited to (1) low manufacturing cost (e.g., accomplished by transferring red-green-blue micro LED pixels in one pass from a silicon wafer to a display backplane resulting in faster transfer rate and higher yield (e.g., lower transfer-related defects on the display), (2) low power consumption (e.g., accomplished by realizing high efficiency red, green and blue micro LEDs at the same time), and/or (3) a projected power reduction of approximately 3-5× compared to OLED technology. In an embodiment, power reduction is achieved with micro LED displays based on the fabrication of LEDs with high power efficacies for all three color LED emitters.

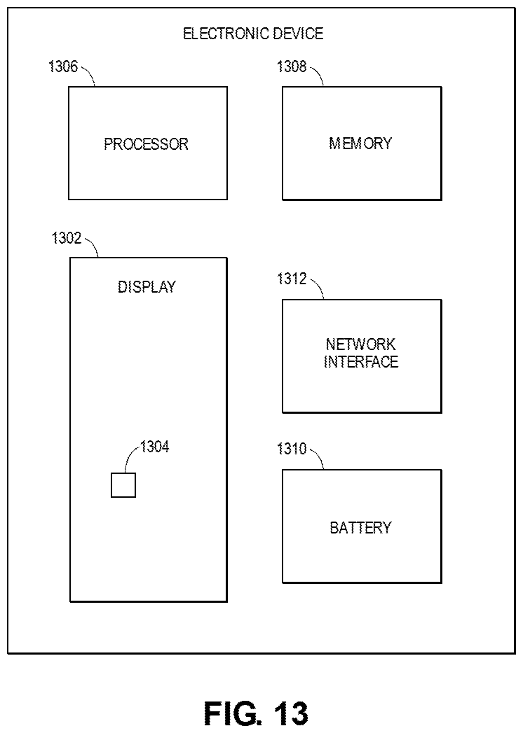

FIG. 13 is an electronic device having a display, in accordance with embodiments of the present disclosure. Referring to FIG. 13, an electronic device 1300 has a display or display panel 1302 with a micro-structure 1304. The display may also have glass layers and other layers, circuitry, and so forth. The display panel 1302 may be a micro-LED display panel. As should be apparent, only one microstructure 1304 is depicted for clarity, though a display panel 1302 will have an array or arrays of microstructures including truncated nanopyramid LEDs.

The electronic device 1300 may be a mobile device such as smartphone, tablet, notebook, smartwatch, and so forth. The electronic device 1300 may be a computing device, stand-alone display, television, display monitor, vehicle computer display, the like. Indeed, the electronic device 1300 may generally be any electronic device having a display or display panel.

The electronic device 1300 may include a processor 1306 (e.g., a central processing unit or CPU) and memory 1308. The memory 1308 may include volatile memory and nonvolatile memory. The processor 1306 or other controller, along with executable code store in the memory 1308, may provide for touchscreen control of the display and well as for other features and actions of the electronic device 1300.

In addition, the electronic device 1300 may include a battery 1310 that powers the electronic device including the display panel 1302. The device 1300 may also include a network interface 1312 to provide for wired or wireless coupling of the electronic to a network or the internet. Wireless protocols may include Wi-Fi (e.g., via an access point or AP), Wireless Direct®, Bluetooth®, and the like. Lastly, as is apparent, the electronic device 1300 may include additional components including circuitry and other components.

Thus, embodiments described herein include micro light-emitting diode structures, displays, display fabrication processes, and assembly apparatuses.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example embodiment 1: A light-emitting diode structure includes a GaN truncated nanopyramid above a substrate, and an InGaN active layer over the GaN truncated nanopyramid.

Example embodiment 2: The light-emitting diode structure of example embodiment 1, wherein the InGaN active layer is an approximately Ino.5Gao.5N material layer, and the light-emitting diode structure is a red-emitting diode structure.

Example embodiment 3: The light-emitting diode structure of example embodiment 1, wherein the InGaN active layer is an approximately Ino.35Gao.65N material layer, and the light-emitting diode structure is a green-emitting diode structure.

Example embodiment 4: The light-emitting diode structure of example embodiment 1, wherein the InGaN active layer is an approximately Ino.2Gao.8N material layer, and the light-emitting diode structure is a blue-emitting diode structure.

Example embodiment 5: The light-emitting diode structure of example embodiment 1, 2, 3 or 4, further including a cladding layer over the InGaN active layer, the cladding layer including gallium and nitrogen.

Example embodiment 6: The light-emitting diode structure of example embodiment 5, wherein the GaN truncated nanopyramid is N-type, and the cladding layer is P-type.

Example embodiment 7: The light-emitting diode structure of example embodiment 1, 2, 3, 4, 5 or 6, wherein the substrate is a silicon substrate or a sapphire substrate.

Example embodiment 8: A micro light emitting diode pixel structure includes a backplane including a glass substrate having an insulating layer disposed thereon, and a pixel thin film transistor circuit disposed in and on the insulating layer, the pixel thin film transistor circuit including a gate electrode and a channel. The micro light emitting diode pixel structure also includes a front plane including a metal pad coupled to the pixel thin film transistor circuit of the backplane, a micro light emitting diode device bonded to the metal pad, where the micro light emitting diode device is a truncated nanopyramid-based micro light emitting diode device, and an insulating layer surrounding the micro light emitting diode device.

Example embodiment 9: The micro light emitting diode pixel structure of example embodiment 8, wherein the metal pad is coupled to the pixel thin film transistor circuit of by a reflective plate or mirror.

Example embodiment 10: The micro light emitting diode pixel structure of example embodiment 8 or 9, further including a transparent conducting oxide layer disposed above the insulating layer.

Example embodiment 11: The micro light emitting diode pixel structure of example embodiment 8, 9 or 10, wherein the channel of the pixel thin film transistor circuit includes a semiconducting oxide material.

Example embodiment 12: The micro light emitting diode pixel structure of example embodiment 8, 9 or 10, wherein the channel of the pixel thin film transistor circuit includes a low temperature polysilicon material.

Example embodiment 13: A pixel element for a micro-light emitting diode (LED) display panel includes a first color truncated nanopyramid-based LED, a second color truncated nanopyramid-based LED, the second color different than the first color, and a pair of third color truncated nanopyramid-based LEDs, the third color different than the first and second colors. A continuous insulating material layer is laterally surrounding the first color truncated nanopyramid-based LED, the second color truncated nanopyramid-based LED, and the pair of third color truncated nanopyramid-based LEDs.

Example embodiment 14: The pixel element of example embodiment 13, wherein the first color is red, the second color is green, and the third color is blue.

Example embodiment 15: The pixel element of example embodiment 13, wherein the first color is red, the second color is blue, and the third color is green.

Example embodiment 16: The pixel element of example embodiment 13, wherein the first color is blue, the second color is green, and the third color is red.

Example embodiment 17: The pixel element of example embodiment 13, 14, 15, 16, wherein the first color truncated nanopyramid-based LED, the second color truncated nanopyramid-based LED, and the pair of third color truncated nanopyramid-based LEDs have a 2×2 arrangement from a plan view perspective.

Example embodiment 18: The pixel element of example embodiment 13, 14, 15, 16, or 17, wherein the first color truncated nanopyramid-based LED, the second color truncated nanopyramid-based LED, and the pair of third color truncated nanopyramid-based LEDs include gallium nitride (GaN) cores.

Example embodiment 19: The pixel element of example embodiment 13, 14, 15, 16, 17 or 18, wherein the first color truncated nanopyramid-based LED, the second color truncated nanopyramid-based LED, and the pair of third color truncated nanopyramid-based LEDs include indium gallium nitride (InGaN) shells.

Example embodiment 20: The pixel element of example embodiment 13, 14, 15, 16, 17, 18 or 19, wherein the continuous insulating material layer includes silicon oxide or carbon-doped silicon dioxide.

What is claimed is:

1. A light-emitting diode structure, comprising:
a GaN truncated nanopyramid above a substrate; and
an InGaN active layer over the GaN truncated nanopyramid.

2. The light-emitting diode structure of claim 1, wherein the InGaN active layer is an approximately Ino.5Gao.5N material layer, and the light-emitting diode structure is a red-emitting diode structure.

3. The light-emitting diode structure of claim 1, wherein the InGaN active layer is an approximately Ino.35Gao.65N material layer, and the light-emitting diode structure is a green-emitting diode structure.

4. The light-emitting diode structure of claim 1, wherein the InGaN active layer is an approximately Ino.2Gao.8N material layer, and the light-emitting diode structure is a blue-emitting diode structure.

5. The light-emitting diode structure of claim 1, further comprising:
a cladding layer over the InGaN active layer, the cladding layer comprising gallium and nitrogen.

6. The light-emitting diode structure of claim 5, wherein the GaN truncated nanopyramid is N-type, and the cladding layer is P-type.

7. The light-emitting diode structure of claim 1, wherein the substrate is a silicon substrate or a sapphire substrate.

8. A micro light emitting diode pixel structure, comprising:
a backplane, comprising:
a glass substrate having an insulating layer disposed thereon; and
a pixel thin film transistor circuit disposed in and on the insulating layer, the pixel thin film transistor circuit comprising a gate electrode and a channel; and
a front plane, comprising:
a metal pad coupled to the pixel thin film transistor circuit of the backplane;
a micro light emitting diode device bonded to the metal pad, wherein the micro light emitting diode device is a truncated nanopyramid-based micro light emitting diode device; and
an insulating layer surrounding the micro light emitting diode device.

9. The micro light emitting diode pixel structure of claim 8, wherein the metal pad is coupled to the pixel thin film transistor circuit of by a reflective plate or mirror.

10. The micro light emitting diode pixel structure of claim 8, further comprising a transparent conducting oxide layer disposed above the insulating layer.

11. The micro light emitting diode pixel structure of claim 8, wherein the channel of the pixel thin film transistor circuit comprises a semiconducting oxide material.

12. The micro light emitting diode pixel structure of claim 8, wherein the channel of the pixel thin film transistor circuit comprises a low temperature polysilicon material.

13. A pixel element for a micro-light emitting diode (LED) display panel, the pixel element comprising:
a first color truncated nanopyramid-based LED;
a second color truncated nanopyramid-based LED, the second color different than the first color;
a pair of third color truncated nanopyramid-based LEDs, the third color different than the first and second colors; and
a continuous insulating material layer laterally surrounding the first color truncated nanopyramid-based LED, the second color truncated nanopyramid-based LED, and the pair of third color truncated nanopyramid-based LEDs.

14. The pixel element of claim 13, wherein the first color is red, the second color is green, and the third color is blue.

15. The pixel element of claim 13, wherein the first color is red, the second color is blue, and the third color is green.

16. The pixel element of claim 13, wherein the first color is blue, the second color is green, and the third color is red.

17. The pixel element of claim 13, wherein the first color truncated nanopyramid-based LED, the second color truncated nanopyramid-based LED, and the pair of third color truncated nanopyramid-based LEDs have a 2×2 arrangement from a plan view perspective.

18. The pixel element of claim 13, wherein the first color truncated nanopyramid-based LED, the second color truncated nanopyramid-based LED, and the pair of third color truncated nanopyramid-based LEDs comprise gallium nitride (GaN) cores.

19. The pixel element of claim 18, wherein the first color truncated nanopyramid-based LED, the second color truncated nanopyramid-based LED, and the pair of third color truncated nanopyramid-based LEDs comprise indium gallium nitride (InGaN) shells.

20. The pixel element of claim 13, wherein the continuous insulating material layer comprises silicon oxide or carbon-doped silicon dioxide.
